(19) United States
(12) Patent Application Publication
(10) Pub. No.: US 2025/0379071 A1
(43) Pub. Date: Dec. 11, 2025

(54) ULTRAVIOLET IRRADIATION SYSTEM, ULTRAVIOLET IRRADIATION METHOD, AND METHOD OF MANUFACTURING CHIPS

(71) Applicant: DISCO CORPORATION, Tokyo (JP)

(72) Inventors: Aimi YAMATO, Tokyo (JP); Shunichiro HIROSAWA, Tokyo (JP); Takuto KAMIMURA, Tokyo (JP); Koichi NAKA, Tokyo (JP); Masaya KOTANI, Tokyo (JP)

(21) Appl. No.: 19/228,223

(22) Filed: Jun. 4, 2025

(30) Foreign Application Priority Data
Jun. 5, 2024 (JP) 2024-091627
Mar. 19, 2025 (JP) 2025-045445

(51) Int. Cl. H01L 21/67; H01L 21/683; H01L 21/78

(52) U.S. Cl. CPC H01L 21/67115; H01L 21/6836; H01L 21/78

(57) ABSTRACT

An ultraviolet irradiation system irradiates a delivery target with ultraviolet rays. The ultraviolet irradiation system includes a delivery path along which to deliver the delivery target to a treatment apparatus and an ultraviolet irradiator for irradiating the delivery target delivered along the delivery path with ultraviolet rays, in which the ultraviolet irradiator is disposed in the delivery path and includes an ultraviolet emitter for emitting ultraviolet rays.

### BACKGROUND OF THE INVENTION

### Field of the Invention

The present invention relates to a system for and a method of irradiating an object being delivered with ultraviolet rays, and a method of manufacturing chips using the irradiating method.

### Description of the Related Art

According to processes of manufacturing chips to be incorporated in electronic equipment, plate-shaped workpieces, typically semiconductor wafers and resin-sealed package substrates, are successively delivered between and processed by various processing apparatuses. In some of such manufacturing processes, the workpieces are irradiated with ultraviolet rays, in some cases.

When a workpiece is delivered and processed, it is handled in a form of a frame unit in which the workpiece is held on a frame by an adhesive tape. Specifically, a frame unit is assembled by affixing a circular adhesive tape to an annular frame called a ring frame and affixing a disk-shaped workpiece to the adhesive surface of the adhesive tape that is exposed centrally in the annular frame. In one type of frame units, an adhesive tape is affixed to one surface of a workpiece. In another type of frame units, adhesive tapes are affixed to respective opposite surfaces of a workpiece.

Note that, in this specification, an object such as a frame unit to be delivered in the processes described above will hereinafter be referred to as a “delivery target,” whereas an object such as a workpiece held on an adhesive tape in such a delivery target will hereinafter be referred to as a “holdable target.”

The adhesive tape includes an adhesive layer made of an adhesive. The adhesive may be of a material that is curable when it absorbs light having a particular wavelength, such as ultraviolet rays. If a holdable target such as a semiconductor wafer is held on an adhesive tape including such an adhesive, then the bonding power of the adhesive is lowered when it is irradiated with ultraviolet rays.

After a holdable target such as a semiconductor wafer that is held on an adhesive tape has been cut or otherwise processed, the adhesive tape may need to be peeled off the holdable target, depending on details of a process or an operation to be subsequently performed on the holdable target. It has been customary before the adhesive tape is peeled off the holdable target to irradiate the adhesive tape affixed to the holdable target with ultraviolet rays as needed, to reduce the bonding power of the adhesive tape.

For example, for performing a die-bonding process on each of individual chips fabricated by dicing a semiconductor wafer as a holdable target with a cutting apparatus, the holdable target or the frame unit is unloaded from the cutting apparatus and delivered to an ultraviolet irradiation apparatus along a delivery path. In the ultraviolet irradiation apparatus, the holdable target is irradiated with ultraviolet rays to reduce the bonding power of the adhesive tape. Then, the holdable target is unloaded from the ultraviolet irradiation apparatus and delivered to a bonding apparatus along the delivery path. In the bonding apparatus, the chip is peeled off the adhesive tape, and a die-bonding process is then performed on the chip.

Technologies for irradiating chips with ultraviolet rays while delivery targets are being handled in the manner described above are disclosed in Japanese Patent Laid-Open No. 2021-82091 and Japanese Patent Laid-Open No. 2006-40944, for example.

### SUMMARY OF THE INVENTION

Meanwhile, in processing holdable targets such as semiconductor wafers, for example, the production efficiency therefor, i.e., the number of holdable targets to be processed per unit time should be as high as possible, as a matter of course. For achieving an increased level of production efficiency, it is effective to carry out each of the steps involved in handling delivery targets in as short a period of time as possible or to move delivery targets as smoothly as possible between those steps, i.e., to shorten the period of time required to send delivery targets from one treatment step to the next one as much as possible.

It is therefore an object of the present invention to provide an ultraviolet irradiation system, an ultraviolet irradiation method, and a method of manufacturing chips which are able to irradiate delivery targets requiring irradiation with ultraviolet rays efficiently with ultraviolet rays.

In accordance with an aspect of the present invention, there is provided an ultraviolet irradiation system for irradiating a delivery target with ultraviolet rays, including a delivery path along which to deliver the delivery target to a treatment apparatus, and an ultraviolet irradiator for irradiating the delivery target delivered along the delivery path with ultraviolet rays, the ultraviolet irradiator being disposed in the delivery path and including an ultraviolet emitter for emitting ultraviolet rays.

In the aspect of the present invention, the delivery path may include at least a portion disposed above the treatment apparatus and the ultraviolet emitter may be housed in a casing disposed in the portion of the delivery path disposed above the treatment apparatus.

In the aspect of the present invention, the ultraviolet irradiation system may further include a delivery carriage movable on and along the delivery path. The delivery carriage includes a frame having a plurality of wheels traveling on the delivery path, a support for supporting the delivery target on the frame, and a lifting and lowering unit mounted on the frame for suspending and lifting and lowering the delivery target through an opening defined in and vertically extending through the delivery path. The ultraviolet irradiator irradiates the delivery carriage on the delivery path with the ultraviolet rays.

In the aspect of the present invention, the ultraviolet irradiator may be disposed to apply the ultraviolet rays from below a delivery surface of the delivery path to a region above the delivery surface, and the delivery surface of a portion of the delivery path that is irradiated with the ultraviolet rays may be provided as a transmissive area that is made of a material that is transmissive of the ultraviolet rays.

In the aspect of the present invention, the delivery surface of the portion of the delivery path that is provided as the transmissive area may lie flush with the delivery surface of the other portion of the delivery path.

In the aspect of the present invention, the support of the delivery carriage may include either a structure that supports the delivery target housed in a receptacle or a receptacle housing the delivery target therein, and the receptacle has at least a portion made of a material that is transmissive of ultraviolet rays.

In the aspect of the present invention, the delivery target may include a frame unit including a plate-shaped holdable target, a frame surrounding the holdable target, and an adhesive tape to which the holdable target is affixed by an ultraviolet-curable adhesive and which is affixed to the frame.

In accordance with another aspect of the present invention, there is provided an ultraviolet irradiation method of irradiating a delivery target with ultraviolet rays, the method including performing treatment on the delivery target with a treatment apparatus, delivering the delivery target outside the treatment apparatus, and irradiating the delivery target that is being delivered outside the treatment apparatus with ultraviolet rays.

In the other aspect of the present invention, the irradiating the delivery target that is being delivered with the ultraviolet rays may include controlling a period of time during which the delivery target is irradiated with the ultraviolet rays by controlling at least either a speed at which the delivery target is delivered or a period of time during which the delivery target stops with respect to an ultraviolet irradiator that irradiates the delivery target with the ultraviolet rays.

In accordance with a further aspect of the present invention, there is provided a method of manufacturing chips with the ultraviolet irradiation method described above, in which the delivery target includes a plate-shaped holdable target, a frame surrounding the holdable target, and an adhesive tape to which the holdable target is affixed by an ultraviolet-curable adhesive and which is affixed to the frame. The method of manufacturing chips includes, before delivering the delivery target outside the treatment apparatus, dividing the holdable target into chips, and after delivering the delivery target outside the treatment apparatus, removing the chips from the adhesive tape.

In the further aspect of the present invention, the step of irradiating the delivery target that is being delivered may include controlling a period of time during which the delivery target is irradiated with the ultraviolet rays by controlling at least either a speed at which the delivery target is delivered or a period of time during which the delivery target stops with respect to an ultraviolet irradiator that irradiates the delivery target with the ultraviolet rays.

With the ultraviolet irradiation system, the ultraviolet irradiation method, and the method of manufacturing chips according to the aspects of the present invention, since the delivery target is irradiated with ultraviolet rays while the delivery target is being delivered on and along the delivery path, the delivery target that needs to be irradiated with ultraviolet rays is irradiated with ultraviolet rays efficiently.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view illustrating by way of example a delivery target handled by an ultraviolet irradiation system and a receptacle housing the delivery target therein;

FIG. 2 is a perspective view illustrating by way of example a delivery carriage for delivering the delivery target illustrated in FIG. 1, as viewed obliquely from above;

FIG. 3 is a perspective view illustrating the delivery carriage illustrated in FIG. 2, as viewed in another direction, i.e., from obliquely below;

FIG. 4 is a block diagram of the ultraviolet irradiation system, illustrating connections between components thereof;

FIG. 5 is a schematic perspective view illustrating by way of example treatment apparatuses connected to the ultraviolet irradiation system and a delivery path along which delivery targets are to be delivered to the treatment apparatuses;

FIG. 6 is a fragmentary schematic plan view illustrating by way of example the delivery path in the ultraviolet irradiation system;

FIG. 7 is a schematic perspective view illustrating by way of example certain parts of the ultraviolet irradiation system; and

FIG. 8 is a flowchart illustrating by way of example the sequence of an ultraviolet irradiation method and a method of manufacturing chips using the ultraviolet irradiation method.

### DETAILED DESCRIPTION OF THE PREFERRED EMBODIMENT

A preferred embodiment of the present invention will be described in detail below with reference to the accompanying drawings. An ultraviolet irradiation system according to the present embodiment includes a delivery path along which delivery targets are to be delivered between a plurality of apparatuses and is arranged to irradiate delivery targets delivered along the delivery path with ultraviolet rays.

According to the embodiment to be described below, a apparatus to which delivery targets are to be delivered in the ultraviolet irradiation system is illustrated as a cutting apparatus by way of example. However, the ultraviolet irradiation system may be arranged to deliver delivery targets to any apparatuses. For example, delivery targets may be delivered to a processing apparatus other than the cutting apparatus, e.g., a laser processing apparatus, in the ultraviolet irradiation system.

The delivery path as a component of the ultraviolet irradiation system may be arranged to deliver delivery targets successively to a plurality of processing apparatuses of different types that are used to process the delivery targets in a sequence.

The ultraviolet irradiation system may be arranged to deliver delivery targets to various apparatuses used in any treatment processes ancillary to the processing of the delivery targets. Specifically, destinations to which delivery targets are to be delivered in the ultraviolet irradiation system may include a tape affixing apparatus, a cleaning apparatus, and an inspection apparatus, for example, that are not intended to process the holdable targets themselves that are included in the delivery targets. In this specification, those apparatuses will hereinafter be referred to as treatment apparatuses.

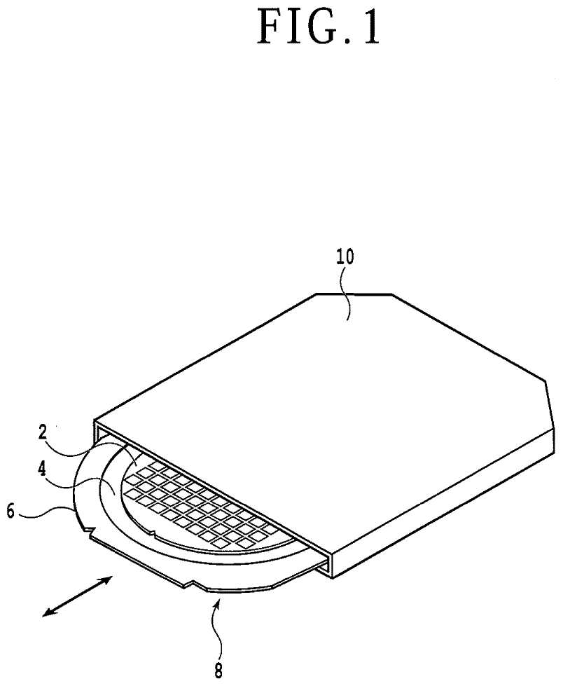

FIG. 1 illustrates in perspective by way of example a delivery target handled by the ultraviolet irradiation system according to the present embodiment and a receptacle housing the delivery target therein. The delivery target, denoted by 8, includes a frame unit including a plate-shaped object such as a semiconductor wafer, for example, as a holdable target 2. The holdable target 2 is secured to a circular adhesive tape 4 having a central region affixed to the holdable target 2 and an outer peripheral region affixed to an annular frame 6.

The holdable target 2 includes a disk-shaped semiconductor wafer made of a semiconductor material such as silicon, for example. The holdable target 2 has a plurality of rectangular areas demarcated by a grid of intersecting streets or projected dicing lines. Devices such as integrated circuits (ICs), light-emitting diodes (LEDs), or microelectromechanical systems (MEMS) devices, for example, are constructed respectively in the demarcated areas on a face side, i.e., upper surface, of the holdable target 2. The holdable target 2 will be divided along the projected dicing lines into a plurality of individual device chips including the respective devices.

The holdable target 2 is not limited to any particular materials, shapes, structures, sizes, types, and applications, for example. The holdable target 2 may include a wafer made of any of semiconductors other than silicon, e.g., GaAs, InP, GaN, or SiC, glass, ceramic, resin, or metal, for example. The devices formed in the holdable target 2 are not limited to any particular types, numbers, shapes, structures, sizes, and layouts, for example. The holdable target 2 may even be free of the devices. Moreover, the holdable target 2 may include a package substrate such as a chip-size package (CSP) substrate or a quad flat non-leaded package (QFN) substrate, for example.

The adhesive tape 4 includes a flexible sheet-shaped base made of a resin such as polyolefin, polyvinyl chloride, or polyethylene terephthalate, for example, and an adhesive layer disposed on at least one surface of the base. The adhesive layer provides an adhesive surface on the at least one surface of the base.

Members shaped as thin surfaces are occasionally termed as a “sheet” or a “film” depending on their thickness. According to the present embodiment, however, thin surface-shaped objects will hereinafter be referred to as a “sheet” regardless of numerical values representing their specific thicknesses.

The adhesive layer of the adhesive tape 4 is made of an adhesive that can be cured upon exposure to ultraviolet rays, i.e., an ultraviolet-curable adhesive. The “ultraviolet rays” generally represent electromagnetic waves having wavelengths in a range from approximately 100 nm to 400 nm. However, some materials that are selected as adhesives may be cured by being exposed to electromagnetic waves having other wavelengths.

The frame 6 includes an annular frame referred to as a “ring frame,” for example. The frame 6 has a central opening defined in a central region thereof. As described above, the outer peripheral region of the adhesive tape 4 is affixed to the frame 6, whereas a portion of the remainder of the adhesive tape 4, i.e., the central region of the adhesive tape 4, is affixed to the holdable target 2. The holdable target 2, the adhesive tape 4, and the frame 6 that are assembled together jointly provide the frame unit 8 as the delivery target handled by the ultraviolet irradiation system.

The frame 6 as a component of the frame unit 8 may not necessarily be of an annular shape. The frame 6 may be of a shape, e.g., a C-shape, that surrounds the adhesive surface of the adhesive tape 4 to which the holdable target 2 is affixed.

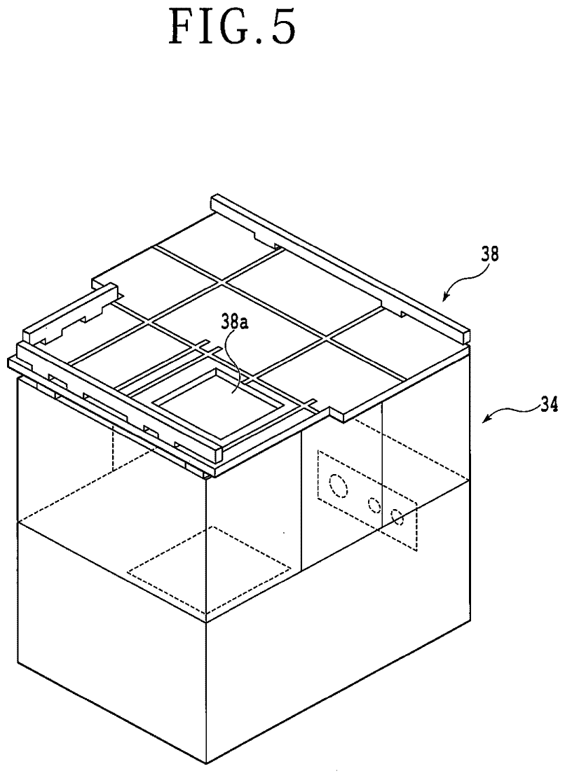

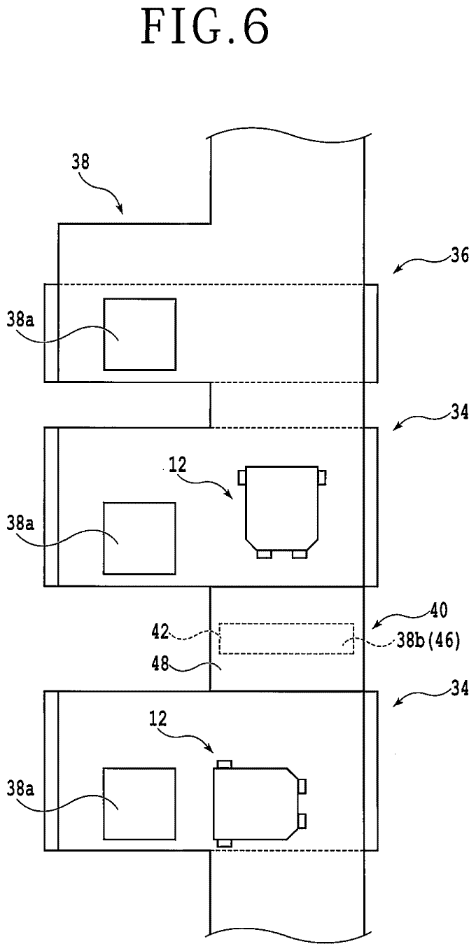

When the ultraviolet irradiation system is in operation, each frame unit is delivered between treatment apparatuses 34 (see FIGS. 5 and 6) while being housed in a receptacle 10 illustrated in FIG. 1. As illustrated in FIG. 1, the receptacle 10 includes a low-profile casing capable of housing a single frame unit, i.e., a delivery target, 8 therein.

Specifically, the receptacle 10 is shaped as a thin hexagonal prism in whole and has a space defined therein for housing a delivery target 8 as a frame unit. The receptacle 10 has a slot defined in a side wall thereof. The internal space in the receptacle 10 communicates through the slot with the external space around the receptacle 10. The delivery target 8 can be taken into and out of the internal space in the receptacle 10 through the slot.

The receptacle 10 includes at least a portion made of a material that is transmissive of ultraviolet rays for thereby allowing the delivery target 8 housed in the receptacle 10 to be irradiated with ultraviolet rays applied from an external source. The material transmissive of ultraviolet rays refers to a material that is transmissive of a dose of ultraviolet rays that is practically effective enough to cure the adhesive of the adhesive tape 4 included in the delivery target 8.

The dose of ultraviolet rays that is transmitted through the material varies depending on the substance of the material, the thickness thereof, and the like. For example, if the receptacle 10 is made of a particular material, then the dose of ultraviolet rays that is transmitted through the particular material, i.e., the ratio of the dose of ultraviolet rays within the receptacle 10 to the dose of ultraviolet rays outside the receptacle 10 when the ultraviolet rays are applied to the portion of the particular material from an external source, may be 50% or more.

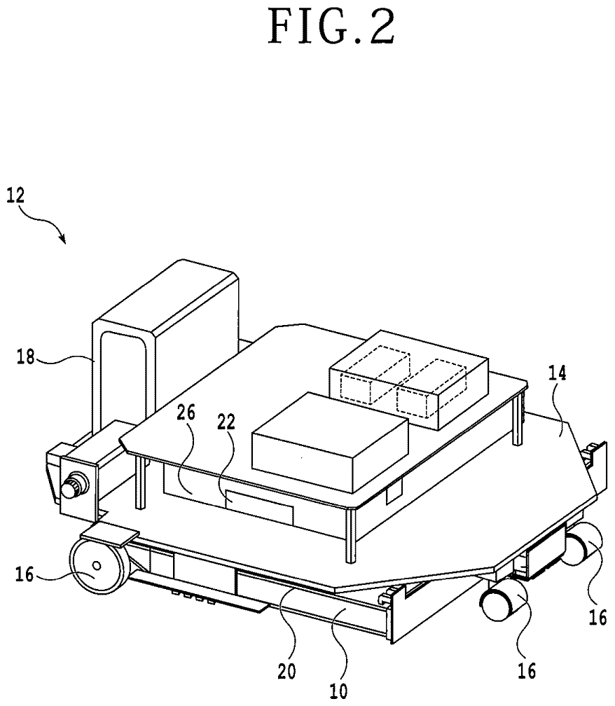

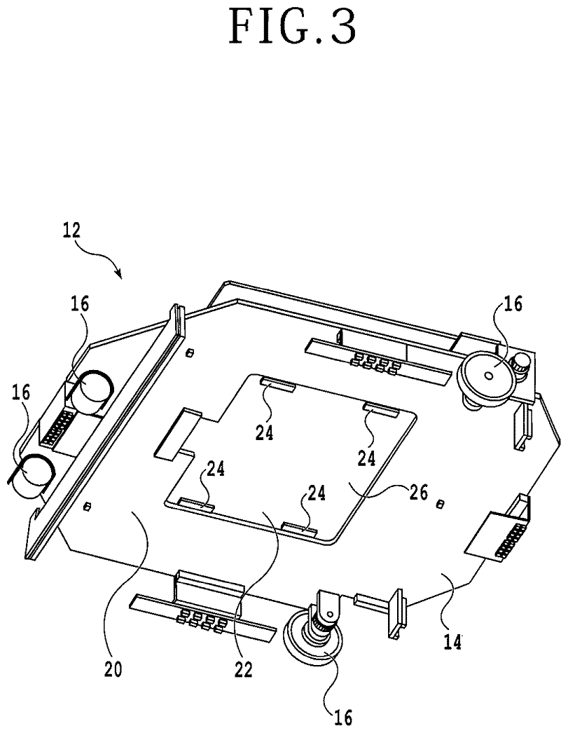

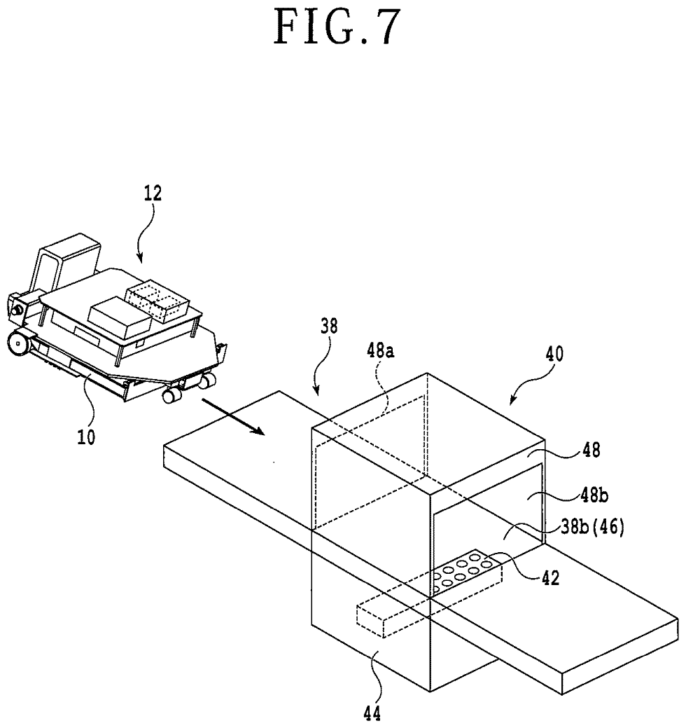

Which portion of the receptacle 10 should be transmissive of ultraviolet rays depends on a direction in which the ultraviolet rays are applied to the receptacle 10 at a time at which a delivery carriage 12 (see FIGS. 2 and 3) that supports and delivers the receptacle 10 housing the delivery target 8 therein passes through an ultraviolet irradiator 40 (see FIGS. 6 and 7) to be described later. Specifically, the portion of the receptacle 10 that is irradiated with ultraviolet rays by the ultraviolet irradiator 40 on one side of the delivery target 8 housed in the receptacle 10 should be made of a material that is transmissive of the ultraviolet rays.

According to the present embodiment, the receptacle 10 is supported on a lower side of the delivery carriage 12 (see FIGS. 2 and 3) such that the receptacle 10 has a lower surface exposed downwardly, and ultraviolet rays are applied from below to the delivery carriage 12. Therefore, the portion of the receptacle 10 that provides the lower surface thereof when the receptacle 10 is delivered by the delivery carriage 12 may be made of a material such as acryl or glass that is transmissive of ultraviolet rays. As a matter of course, the receptacle 10 may be made of a material that is transmissive of ultraviolet rays in its entirety.

Taking it into account that the delivery target 8 housed in the receptacle 10 is to be irradiated with ultraviolet rays, the receptacle 10 should house therein a single delivery target 8 or two delivery targets 8 stacked in superposed relation. The receptacle 10 should not house therein three or more delivery targets 8 stacked in superposed relation because an intermediate delivery target or targets 8 would not be sufficiently irradiated with ultraviolet rays.

If a single delivery target 8 is housed in the receptacle 10, then the receptacle 10 is supported on the delivery carriage 12 with the adhesive tape 4 positioned beneath the holdable target 2, and ultraviolet rays are applied from below to the receptacle 10. The present embodiment is based on this set-up of the delivery target 8, the receptacle 10, and the delivery carriage 12. Alternatively, the receptacle 10 may be supported on the delivery carriage 12 with the adhesive tape 4 positioned over the holdable target 2, and ultraviolet rays may be applied from above to the receptacle 10.

If two delivery targets 8 are housed in the receptacle 10, then the two delivery targets 8 in the receptacle 10 are stacked such that two holdable targets 2 are sandwiched between the two adhesive tapes 4, and ultraviolet rays are applied to the receptacle 10 from its both sides, i.e., from above and below, perpendicularly to the planes of the two adhesive tapes 4. This set-up of the delivery target 8, the receptacle 10, and the delivery carriage 12 will be omitted from illustration.

According to the present embodiment, the delivery target 8 is delivered while being housed in the receptacle 10, as described above. However, the delivery target 8 may be delivered while being not housed in the receptacle 10 or may be supported on and delivered by the delivery carriage 12 while being partly housed in the receptacle 10.

FIGS. 2 and 3 illustrate by way of example the delivery carriage 12 for delivering the delivery target 8 illustrated in FIG. 1. FIG. 2 illustrates in perspective the delivery carriage 12 as viewed obliquely from above, and FIG. 3 illustrates in perspective the delivery carriage 12 as viewed obliquely from below.

The delivery carriage 12 includes a frame 14 providing a main carriage structure, a plurality of wheels 16 rotatably mounted on a lower surface of the frame 14, a drive unit 18 for driving the wheels 16, a support 20 for supporting the delivery target 8 on the frame 14, and a lifting and lowering unit 22 for lifting and lowering the delivery target 8.

The frame 14 is a structural body that supports thereon various components included in the delivery carriage 12, and is shaped as a plate in FIGS. 2 and 3. The wheels 16 include a total of four wheels 16 that include a pair of wheels 16 disposed in respective positions on a lower surface of the frame 14 near a front end thereof and a pair of wheels 16 disposed in respective positions on the lower surface of the frame 14 near a rear end thereof. The wheels 16 act as a mechanism for enabling the delivery carriage 12 to travel on a delivery path 38 (see FIGS. 5 through 7) to be described later. The wheels 16 are held in rolling contact with an upper surface, i.e., a delivery surface, of the delivery path 38 and rotate about their axles to enable the delivery carriage 12 to travel on the delivery path 38.

The drive unit 18 for driving the pair of wheels 16 near the front end of the frame 14 is mounted on the front end of the frame 14. The drive unit 18 includes a mechanism such as an electric motor for generating rotary power to drive the wheels 16, a pulley and a belt mechanism for transferring the rotary power from the electric motor to the axles of the wheels 16, a battery for supplying electric power to energize the electric motor, and terminals for charging the battery from an external power source.

The support 20 for supporting the delivery target 8 is disposed beneath the frame 14. According to the present embodiment, the support 20 is surrounded by the front and rear pairs of the wheels 16, i.e., the total of four wheels 16, as viewed in plan, and is defined as a region below the lower surface of the frame 14 and above the lower ends of the wheels 16. The receptacle 10 that houses the delivery target 8 therein is supported in the support 20 by the lifting and lowering unit 22 described later.

When the delivery target 8 is delivered by the delivery carriage 12, since the receptacle 10 is supported with its lower surface positioned above the lower ends of the wheels 16, the receptacle 10 does not contact the delivery path 38 (see FIGS. 5 through 7) while the delivery carriage 12 is traveling on the delivery path 38.

According to the illustrated embodiment, the delivery target 8 is supported in the support 20 by being housed in the receptacle 10 that is supported in the support 20. However, the support 20 may be constructed as a receptacle for housing the delivery target 8. According to such a modification, the support 20 that is constructed as a receptacle may have a lower surface made of a material that is transmissive of ultraviolet rays, for example, as in the receptacle 10 described above. Alternatively, the support 20 of the delivery carriage 12 may be constructed to support the delivery target 8 without a receptacle for supporting the delivery target 8.

The lifting and lowering unit 22 for supporting the receptacle 10 in the support 20 and lifting and lowering the receptacle 10 with respect to the frame 14 is disposed in an area of the upper surface of the frame 14 that overlaps the support 20 as viewed in plan. The lifting and lowering unit 22 operates to lower the receptacle 10 and place the lowered receptacle 10 in a predetermined position and also to lift the receptacle 10 from the predetermined position and support the lifted receptacle 10. The predetermined position where the receptacle 10 is to be placed refers to a position in each of the treatment apparatuses 34 (see FIGS. 5 and 6) or a position in a loader/unloader 36 (see FIG. 6) where the delivery target 8 is to be temporarily placed.

As illustrated in FIG. 3, the lifting and lowering unit 22 has a plurality of, i.e., four in the embodiment, hangers 24 that can be reeled out and extended downwardly from the lower surface of the frame 14. In FIG. 3, the hangers 24 are illustrated as retracted upwardly rather than extended downwardly.

The hangers 24 are arranged to have the receptacle 10 suspended from their distal ends. The hangers 24 can be reeled out downwardly and wound upwardly by a drive mechanism 26 mounted on the frame 14. Each of the hangers 24 may include a flat belt having an appropriate width or a wire rope that can be reeled out and wound.

When the hangers 24 with the receptacle 10 suspended thereby are reeled out downwardly from the support 20 by the drive mechanism 26, the receptacle 10 is lowered by gravity from the frame 14 into the predetermined position over a distance commensurate with the length by which the hangers 24 are reeled out. When the hangers 24 are wound by the drive mechanism 26 from the predetermined position where the the receptacle 10 has been placed, the receptacle 10 is lifted and supported in the support 20.

If the hangers 24 include flat belts, respectively, then the receptacle 10 suspended by the hangers 24 is less liable to swing in horizontal directions along the widths of the belts. Therefore, the hangers 24 in the form of flat belts should be oriented in horizontal directions such that the horizontal directions along the widths of the belts are aligned with the directions along which the delivery target 8 is taken into and out of the receptacle 10 as indicated by the double-headed arrow in FIG. 1, i.e., the directions along which the delivery target 8 and the slot in the side wall of the receptacle 10 are aligned with each other, in order to prevent the delivery target 8 from jumping out of the slot in the side wall of the receptacle 10 while the delivery target 8 is being lifted or lowered.

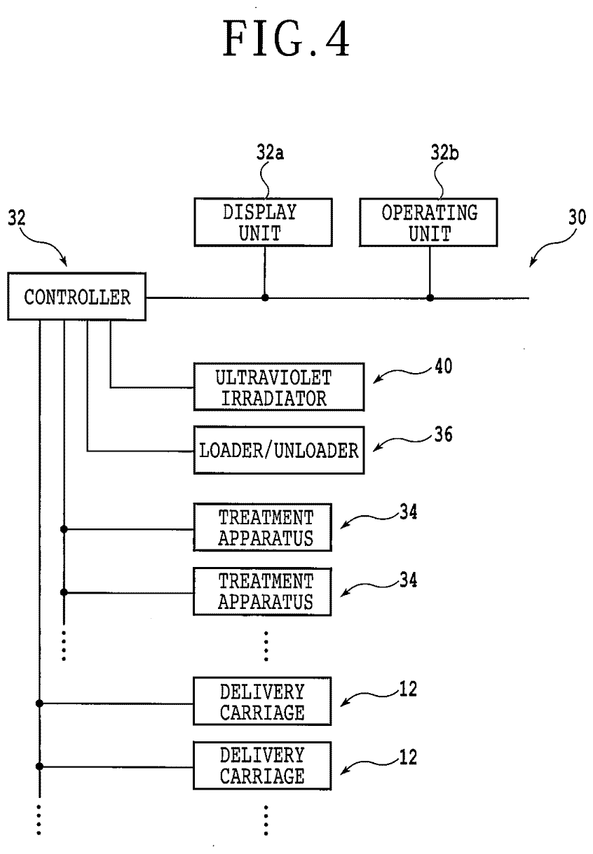

FIGS. 4 through 7 illustrate the ultraviolet irradiation system according to the present embodiment that delivers the delivery target 8 illustrated in FIG. 1 with the delivery carriage 12 illustrated in FIGS. 2 and 3 and irradiates the delivery target 8 with ultraviolet rays.

FIG. 4 illustrates in block form connections between components of the ultraviolet irradiation system, denoted by 30. As illustrated in FIG. 4, the ultraviolet irradiation system 30 includes a controller 32 for controlling operation of components making up and/or to be connected to the ultraviolet irradiation system 30, including the delivery carriages 12, the ultraviolet irradiator 40, the treatment apparatuses 34, and the loader/unloader 36.

The controller 32 includes a computer, for example, and also includes a processor such as a central processing unit (CPU) and various types of memories that act as a main storage unit and an auxiliary storage unit. The controller 32 generates various control signals for the components by executing programs stored in the memories.

The controller 32 is electrically connected to the components of the ultraviolet irradiation system 30 through a wireless or wired link. The controller 32 outputs the generated control signals to the components through the wireless or wired link, thereby controlling various necessary operations such as the delivery of the delivery target 8 with the delivery carriage 12, the irradiation of the delivery target 8 with ultraviolet rays by the ultraviolet irradiator 40, and the transfer of the delivery target 8 between the treatment apparatuses 34 as well as the loader/unloader 36 and the delivery carriage 12.

Also, the components send various signals to the controller 32 in order for the controller 32 to monitor the components for their operation states.

To the controller 32, there are electrically connected a display unit 32a and an operating unit 32b. The display unit 32a includes a display panel for displaying the operation states of the components as grasped by the controller 32 by way of visual symbols such as characters and images. The operating unit 32b includes an interface that allows an operator to enter various operation commands into the controller 32. For example, the operating unit 32b includes a keyboard and mouse, an operating console having various switches, or a touch-panel display, for example. In a case in which the operating unit 32b includes a touch-panel display, the touch-panel display may function as the operating unit 32b and also the display unit 32a.

FIG. 5 schematically illustrates in perspective by way of example a treatment apparatus 34 coupled to the ultraviolet irradiation system 30 and a delivery path 38 in the ultraviolet irradiation system 30 for delivering the delivery target 8 to the treatment apparatus 34. FIG. 6 schematically illustrates in plan by way of example the delivery path 38 in the ultraviolet irradiation system 30.

The treatment apparatus 34 includes, for example, a cutting apparatus including a cutting unit for cutting the holdable target 2 (see FIG. 1) such as a semiconductor wafer, for example, as part of the delivery target 8. The cutting unit includes a spindle with an annular cutting blade mounted on its distal end. The cutting unit operates by rotating the cutting blade and causing the rotating cutting blade to cut into the holdable target 2 to divide the holdable target 2.

The treatment apparatus 34 is not limited to a particular type, and may be any of various apparatuses for processing the holdable target 2 in various ways. For example, the treatment apparatus 34 may include a grinding apparatus including a grinding unit for grinding the holdable target 2 or a polishing apparatus including a polishing unit for polishing the holdable target 2.

In a case in which the treatment apparatus 34 is a grinding apparatus, the grinding unit thereof includes a spindle with an annular grinding wheel mounted on its distal end and a plurality of grindstones fixed to the grinding wheel. The grinding apparatus operates by rotating the grinding wheel and bringing the grindstones on the rotating grinding wheel into abrasive contact with the holdable target 2 to grind the holdable target 2.

In a case in which the treatment apparatus 34 is a polishing apparatus, it includes a spindle with a disk-shaped polishing pad mounted on its distal end. The polishing apparatus operates by rotating the polishing pad and bringing the rotating polishing pad into abrasive contact with the holdable target 2 to polish the holdable target 2.

Alternatively, the treatment apparatus 34 may include a laser processing apparatus for processing the holdable target 2 with a laser beam applied thereto. The laser processing apparatus includes a laser beam applying unit for applying a laser beam to the holdable target 2. The laser beam applying unit includes a laser oscillator for emitting a laser beam having a predetermined wavelength by way of pulsed oscillation and a beam condenser for focusing the laser beam emitted from the laser oscillator. The laser processing apparatus operates by emitting the laser beam from the laser oscillator and focusing the emitted laser beam on the surface of the holdable target 2 or within the holdable target 2 with the beam condenser to process the holdable target 2 with the focused laser beam.

A plurality of pipes, not depicted, are connected to a side panel of the treatment apparatus 34. The pipes include supply ducts for supplying various liquids and gases to the treatment apparatus 34 that are required in processing the holdable target 2 and discharge ducts for discharging the liquids and the gases from the treatment apparatus 34.

The ultraviolet irradiation system 30 includes, in addition to the treatment apparatuses 34, the loader/unloader 36 that is able to house the delivery target 8 therein. The delivery target 8 that is housed in the loader/unloader 36 is transferred to the delivery carriage 12 as needed and then delivered by the delivery carriage 12. The delivery target 8 that is held by the delivery carriage 12 is transferred to the loader/unloader 36 as needed.

The delivery path 38 along which to deliver delivery targets 8 to the treatment apparatuses 34 and the loader/unloader 36 is disposed above the treatment apparatuses 34 and the loader/unloader 36 over spaces between the treatment apparatuses 34 and between the treatment apparatuses 34 and the loader/unloader 36.

More specifically, the multiple treatment apparatuses 34 and the loader/unloader 36 are coupled to each other by the delivery path 38 disposed above the treatment apparatuses 34 and the loader/unloader 36. Delivery carriages 12 for delivering the respective delivery targets 8 are disposed on and travel along the delivery path 38. Though two delivery carriages 12 are illustrated by way of example in FIG. 6, there is no limitation on the number of delivery carriages 12 disposed on the delivery path 38.

The delivery path 38 extends along a plane in horizontal directions above the treatment apparatuses 34 and the loader/unloader 36, and provides an upper delivery surface on which the delivery carriages 12 travel with their wheels 16 (see FIGS. 2 and 3) being held in rolling contact therewith. The plane along which the delivery path 38 extends in the horizontal directions refers to not only a strict horizontal plane perpendicular to the gravitational direction, but also a generally horizontal plane, a plane that may practically be deemed generally horizontal, or a plane that is inclined or curved to a certain extent with respect to a horizontal plane.

Also, the delivery path 38 may possibly have steps due to height or other dimensional differences between the treatment apparatuses 34 and the loader/unloader 36. However, no problem will arise if those steps are small enough for the wheels 16 of the delivery carriages 12 to move over. The plane along which the delivery path 38 extends in the horizontal directions should be construed as covering such small steps of the delivery path 38.

The delivery path 38 has openings 38a defined at certain positions therein that extend vertically through the delivery path 38. Each of the openings 38a acts as a passage through which a delivery target 8 can be transferred between the delivery path 38 and an apparatus disposed therebelow, i.e., one of the treatment apparatuses 34 and the loader/unloader 36. Therefore, the openings 38a are positioned respectively above the treatment apparatuses 34 and the loader/unloader 36. When a delivery target 8 is to be transferred between the delivery path 38 and one of the treatment apparatuses 34 and the loader/unloader 36, the delivery carriage 12 that carries the delivery target 8 stops at a corresponding one of the openings 38a and then the lifting and lowering unit 22 reels out or winds the hangers 24 to suspend the delivery target 8 from or toward the delivery carriage 12 through the opening 38a, thereby moving the delivery target 8 between the delivery carriage 12 and the one of the treatment apparatuses 34 and the loader/unloader 36.

In a case in which the delivery target 8 is a frame unit including a semiconductor wafer as the holdable target 2 and one of the treatment apparatuses 34 is a cutting apparatus for cutting the semiconductor wafer, the opening 38a in the delivery path 38 above the treatment apparatus 34 is positioned above a support base on the treatment apparatus 34. The treatment apparatuses 34 and the loader/unloader 36 have respective support bases.

Note that the delivery path 38 may also be of a structure other than the illustrated structure. For example, the delivery path 38 may partly or wholly be disposed in a position or positions not above the treatment apparatuses 34 and the loader/unloader 36.

As illustrated in FIG. 6, the ultraviolet irradiator 40 included in the ultraviolet irradiation system 30 according to the present embodiment is disposed in an intermediate zone on the delivery path 38 for irradiating the delivery targets 8 delivered along the delivery path 38 with ultraviolet rays.

FIG. 7 schematically illustrates in perspective by way of example certain parts of the ultraviolet irradiator 40 included as a principal component of the ultraviolet irradiation system 30. As illustrated in FIG. 7, the ultraviolet irradiator 40 includes an ultraviolet emitter 42 for emitting ultraviolet rays, a casing 44 that houses the ultraviolet emitter 42 therein, an irradiation surface part 46 provided as an upper surface of the casing 44 and also as part of the delivery path 38, and an irradiation chamber 48 that surrounds the irradiation surface part 46 and a delivery carriage 12 that has traveled on the delivery path 38 and entered the ultraviolet irradiator 40.

The ultraviolet emitter 42 is a unit for emitting ultraviolet rays with which to irradiate the delivery target 8. The ultraviolet emitter 42 may include a high-pressure mercury lamp that emits ultraviolet rays by performing an arc discharge on metal vapor or an UV-LED that generates ultraviolet rays from an LED element. Alternatively, the ultraviolet emitter 42 may include any of various light sources capable of emitting light having a wavelength that promotes the curing of the adhesive of the adhesive tape 4 (see FIG. 1).

Note that, in general, ultraviolet rays represent electromagnetic waves having wavelengths in the range from approximately 100 to 400 nm. Each of the ultraviolet irradiator 40 and the ultraviolet emitter 42 according to the present embodiment refers to a mechanism or a unit capable of outputting electromagnetic waves having wavelengths in the range from approximately 100 to 400 nm at an intensity level high enough to exert a particular effect, e.g., the curing of the adhesive of the adhesive tape 4 according to the present embodiment, on the delivery target 8.

The casing 44 refers to an enclosure that houses therein the ultraviolet emitter 42 at a position for irradiating the delivery target 8 traveling on the delivery path 38 with ultraviolet rays. According to the present embodiment, the casing 44 includes a cuboid-shaped box whose upper surface acts as the irradiation surface part 46 through which ultraviolet rays are transmittable. Other portions of the casing 44 than the irradiation surface part 46 are made of a material that blocks the ultraviolet rays applied thereto, or specifically absorbs, reflects, or attenuates the ultraviolet rays to the extent that at least 80% of the ultraviolet rays applied to the irradiation surface part 46 is obstructed thereby.

The irradiation surface part 46 as the upper surface of the casing 44 is made of a material that is transmissive of the ultraviolet rays. Specifically, the irradiation surface part 46 allows the ultraviolet rays emitted from the ultraviolet emitter 42 in the casing 44 to pass upwardly therethrough. According to the present embodiment, the irradiation surface part 46 provides a transmissive area 38b as part of the delivery path 38 of the ultraviolet irradiation system 30, so that the delivery carriage 12 can travel on the upper surface of the irradiation surface part 46, i.e., the transmissive area 38b, when the delivery carriage 12 travels along the delivery path 38.

Stated otherwise, the ultraviolet emitter 42 of the ultraviolet irradiator 40 is disposed below the delivery surface of the delivery path 38 and applies emitted ultraviolet rays from below the delivery surface to a region above the delivery surface. The delivery surface of a portion of the delivery path 38 that is irradiated with the ultraviolet rays applied from below is provided as the transmissive area 38b that is made of the material that is transmissive of the ultraviolet rays.

In a case in which the ultraviolet emitter 42 includes a UV-LED, for example, the ultraviolet emitter 42 is constructed as a rod-shaped light source made up of a row or a plurality of rows of light emitters disposed in the casing 44. The row or rows of light emitters should be oriented perpendicularly to the direction of travel of the delivery carriage 12 along the delivery path 38, for example.

In this fashion, the ultraviolet irradiator 40 is capable of irradiating the delivery carriage 12 on the delivery path 38 with ultraviolet rays.

The irradiation surface part 46 as the transmissive area 38b should preferably lie flush with the other portion of the delivery path 38 than the irradiation surface part 46 for allowing the delivery carriage 12 to travel smoothly along the delivery path 38. However, the upper surface provided by the irradiation surface part 46 may protrude upwardly and/or be dented downwardly from the other portion of the delivery path 38 to a certain extent as long as the delivery carriage 12 can travel uninterruptedly over the irradiation surface part 46.

The irradiation chamber 48 refers to a cover surrounding the irradiation surface part 46 and the delivery carriage 12 that is irradiated with the ultraviolet rays transmitted through the irradiation surface part 46. According to the present embodiment, as illustrated in FIGS. 6 and 7, the irradiation surface part 46, i.e., the transmissive area 38b, is disposed in an intermediate zone on the delivery path 38, and the irradiation chamber 48 is installed as a tunnel-shaped structure having left, right, and upper panels around the transmissive area 38b with respect to the direction along which the delivery carriage 12 travels.

The irradiation chamber 48 is made of a material that does not transmit the ultraviolet rays therethrough, i.e., that blocks the ultraviolet rays, to prevent the ultraviolet rays transmitted through the irradiation surface part 46 from leaking into the space surrounding the irradiation chamber 48. The irradiation chamber 48 has an entrance opening 48a and an exit opening 48b defined therein that are open in the direction of travel of the delivery carriage 12 along the delivery path 38. Doors, shutters, or screens, not depicted, for example, made of a material that does not transmit the ultraviolet rays may be openably and closably mounted respectively in the entrance opening 48a and the exit opening 48b.

While the delivery carriage 12 is being housed in the irradiation chamber 48, the entrance opening 48a and the exit opening 48b may be closed by shutters or the like, not depicted, and the irradiation chamber 48 may be supplied with a gas such as nitrogen gas, after which the delivery target 8 may be irradiated with ultraviolet rays. Radical polymerization of molecules of the ultraviolet-curable adhesive by ultraviolet rays may be obstructed by oxygen. In order to prevent oxygen from obstructing radical polymerization, it is effective to supply a gas free of oxygen to the space around the delivery target 8.

To restrain the obstruction of radical polymerization by oxygen, it is also effective to hermetically seal the irradiation chamber 48 and replace the air in the irradiation chamber 48 with nitrogen gas, for example. However, this process is somewhat time-consuming to perform, and mechanisms are required to hermetically seal the irradiation chamber 48 and replace the air in the irradiation chamber 48 with nitrogen gas.

Another solution is to irradiate the delivery carriage 12 as it travels through the irradiation chamber 48 with ultraviolet rays while supplying nitrogen gas to the irradiation chamber 48 that is separated from the external space to a certain extent, rather than thoroughly hermetically sealing the irradiation chamber 48 and fully replacing the air in the irradiation chamber 48 with nitrogen gas. Even though oxygen is not fully removed from the space around the delivery carriage 12, it is possible to sufficiently prevent the ultraviolet-curing process from being obstructed by oxygen, if the concentration of oxygen around the delivery carriage 12 is lowered to a certain degree.

As illustrated in FIGS. 5 and 6, the treatment apparatuses 34 or the loader/unloader 36 can be disposed below the portions of the delivery path 38 that are positioned in front of and behind the ultraviolet irradiator 40 with respect to the direction of travel of the delivery carriage 12 on the delivery path 38. Although not depicted, a treatment apparatus 34 or a loader/unloader 36 may be disposed below the ultraviolet irradiator 40. According to such a modification, the transmissive area 38b of the delivery path 38 is positioned above the treatment apparatus 34 or the loader/unloader 36, and the ultraviolet emitter 42 is positioned between the transmissive area 38b and the treatment apparatus 34 or the loader/unloader 36.

With the above layout according to the present embodiment, the delivery path 38 is positioned above the treatment apparatus 34 and the loader/unloader 36, and the ultraviolet emitter 42 is housed in the casing 44 on the portion of the delivery path 38 that is disposed above the treatment apparatus 34 and the loader/unloader 36.

The ultraviolet irradiator 40 thus disposed in the intermediate zone on the delivery path 38 can reduce the footprint of the overall ultraviolet irradiation system 30, compared with the layout in which an ultraviolet irradiator is disposed on the same plane as treatment apparatuses and a loader/unloader and they are interconnected by a delivery path. In particular, the ultraviolet irradiation system 30 according to the present embodiment that requires a reduced footprint is useful in industrial clean rooms that need a high maintenance cost and that require a limited installation area.

According to the layout (see FIGS. 5 and 6) in which the delivery path 38 is disposed above the treatment apparatuses 34 and the loader/unloader 36, the ultraviolet irradiator 40 is disposed in the intermediate zone on the delivery path 38, and the casing 44 housing the ultraviolet emitter 42 is disposed on the delivery path 38 disposed above the treatment apparatuses 34 and the loader/unloader 36, the area where the overall ultraviolet irradiation system 30 is installed, i.e., the footprint of the ultraviolet irradiation system 30, can greatly be reduced.

The treatment apparatuses 34 connected to the ultraviolet irradiation system 30 can be assumed to be various processing apparatuses or the like, as described above. According to an example, the treatment apparatuses 34 may include a cutting apparatus and a bonding apparatus that are interconnected by the delivery path 38, and the ultraviolet irradiator 40 may be disposed in a route of the delivery path 38 from the cutting apparatus to the bonding apparatus.

In a process of processing a semiconductor wafer, a cutting apparatus performs a dicing step on a holdable target 2 (see FIG. 1) secured to a delivery target, i.e., a frame unit, 8 by an adhesive tape 4 having an ultraviolet-curable adhesive, thereby dividing the holdable target 2 into chips, and thereafter a bonding apparatus performs a bonding step on the chips produced from the holdable target 2. When the delivery target 8 is irradiated with ultraviolet rays between the dicing step and the bonding step, the adhesive is cured, allowing the chips to be easily peeled off from the adhesive tape 4.

If the ultraviolet irradiator 40 is provided between the cutting apparatus and the bonding apparatus, then the ultraviolet irradiator 40 can irradiate the holdable target 2 with ultraviolet rays while the holdable target 2 is being delivered from the cutting apparatus to the bonding apparatus. As a result, the period of time required to perform the entire semiconductor wafer processing sequence can be shortened.

Also, since the ultraviolet irradiator 40 is disposed in an intermediate zone on the delivery path 38 according to the present embodiment, the ultraviolet irradiator 40 can irradiate the delivery target 8 with ultraviolet rays not only between particular steps described above, but also at a desired time while the delivery target 8 is being delivered to an apparatus connected to the delivery path 38.

For example, delivery targets of one kind are irradiated with ultraviolet rays while they are being delivered from a treatment apparatus, i.e., a first treatment apparatus, to another treatment apparatus, i.e., a second treatment apparatus, whereas delivery targets of another kind are irradiated with ultraviolet rays while they are being delivered from the second treatment apparatus to still another treatment apparatus, i.e., a third treatment apparatus.

Specifically, providing a treatment apparatus is connected to a delivery path that incorporates an ultraviolet irradiator therein, a delivery target before or after being delivered to the equipment can be delivered to an area of the delivery path that incorporates the ultraviolet irradiator and then be irradiated with ultraviolet rays by the ultraviolet irradiator. Consequently, delivery targets can be irradiated with ultraviolet rays in a manner that flexibly meets demands on those delivery targets.

According to the present embodiment, moreover, the delivery target 8 is irradiated with ultraviolet rays while it is being supported on and delivered by the delivery carriage 12. Therefore, when a required area of the delivery target 8 is irradiated with ultraviolet rays in its entirety, the ultraviolet emitter 42 does not need to be moved with respect to the delivery target 8. The ultraviolet emitter 42 remains fixed in a particular position on the delivery path 38, and the delivery carriage 12 is moved on the delivery path 38 to irradiate the entire required area of the delivery target 8 with ultraviolet rays. In other words, the ultraviolet irradiator 40 is not required to have a mechanism for moving the ultraviolet emitter 42 and hence provides a space-saving, low-cost arrangement for irradiating the delivery target 8 with ultraviolet rays.

Moreover, for irradiating the delivery target 8 with ultraviolet rays, it is not necessary to unload the delivery target 8 from the delivery carriage 12 and take the delivery target 8 out of the receptacle 10. The delivery target 8 can be irradiated with ultraviolet rays while the delivery target 8 is being supported on the delivery carriage 12. Accordingly, the period of time required to unload the delivery target 8 from the delivery carriage 12 and take the delivery target 8 out of and back into the receptacle 10 can be saved. As a result, the productivity of a series of processes including irradiation of ultraviolet rays can be enhanced.

The dose of ultraviolet rays required to irradiate the delivery target 8 varies depending on the application and state of the delivery target 8, the structure of the adhesive tape 4, and the like. The dose of ultraviolet rays can be adjusted by controlling the output power of the ultraviolet emitter 42 and/or the period of time during which the delivery target 8 is irradiated with ultraviolet rays. The period of time during which the delivery target 8 is irradiated with ultraviolet rays can be controlled by controlling the speed at which the delivery carriage 12 delivers the delivery target 8 or the period of time during which the delivery target 8 temporarily stops with respect to the ultraviolet irradiator 40.

Specifically, if the dose of ultraviolet rays is to be increased, then the speed of the delivery carriage 12 traveling on the ultraviolet irradiator 40 may be lowered, and if the dose of ultraviolet rays is to be reduced, then the speed of the delivery carriage 12 traveling on the ultraviolet irradiator 40 may be increased. Alternatively, when the ultraviolet rays are applied, if the dose of ultraviolet rays is to be increased, then the period of time during which the delivery target 8 temporarily stops with respect to the ultraviolet irradiator 40 may be increased, and if the dose of ultraviolet rays is to be reduced, then the period of time during which the delivery target 8 temporarily stops with respect to the ultraviolet irradiator 40 may be shortened. The control of the period of time during which the delivery target 8 is irradiated with ultraviolet rays on the basis of the speed of the delivery carriage 12 and the control of the period of time during which the delivery target 8 is irradiated with ultraviolet rays on the basis of the period of time during which the delivery target 8 temporarily stops with respect to the ultraviolet irradiator 40 may also be combined with each other.

According to the present embodiment, the delivery path 38 has its upper surface as the delivery surface with the delivery carriage 12 traveling thereon. However, the delivery path according to the present invention is not structurally limited to the illustrated delivery path 38. The present invention is also applicable to an ultraviolet irradiation system including a delivery mechanism that has a pod-shaped delivery unit suspended from a rail supported on and extending along a factory ceiling and an ultraviolet irradiator disposed in an intermediate zone on a route provided by the rail.

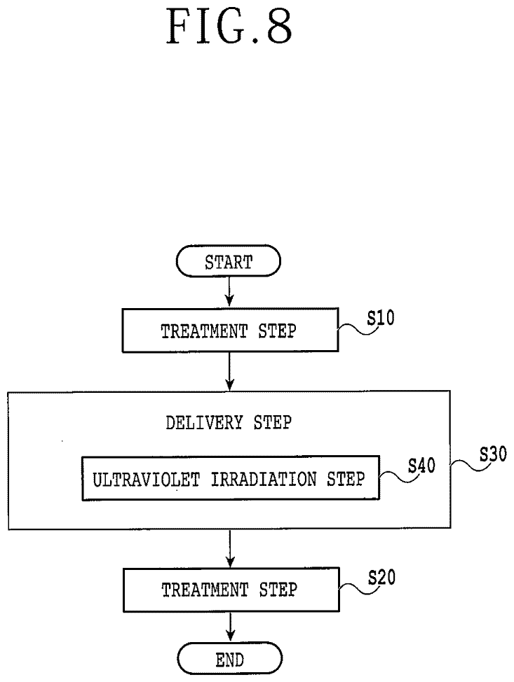

The above process of irradiating a delivery target with ultraviolet rays is illustrated in FIG. 8. FIG. 8 is a flowchart illustrating by way of example the sequence of an ultraviolet irradiation method and a method of manufacturing chips using the ultraviolet irradiation method.

As illustrated in FIG. 8, a delivery target 8 is processed by a treatment apparatus 34 (treatment step S10), after which the delivery target 8 is transferred to another treatment apparatus 34 and processed thereby (treatment step S20).

The delivery target 8 having been subjected to the treatment in one treatment step (step S10) is taken out of one treatment apparatus 34 by a delivery carriage 12 and then delivered along a delivery path 38 to another treatment apparatus 34 (delivery step; step S30). The delivery target 8 is delivered into the other treatment apparatus 34 and subjected to the next treatment step thereby (step S20).

In the delivery step (step S30), the delivery carriage 12 travels along the delivery path 38. While the delivery carriage 12 is traveling in an ultraviolet irradiator 40 disposed in an intermediate zone on the delivery path 38, the delivery carriage 12 is irradiated with ultraviolet rays, and hence, the delivery target 8 that is supported on the delivery carriage 12 is also irradiated with ultraviolet rays (ultraviolet irradiation step; step S40).

In a case in which the above process is applied to a process of manufacturing chips, the delivery target 8 represents the frame unit made up of the holdable target 2 such as a plate-shaped semiconductor wafer, the frame 6 surrounding the holdable target 2, and the adhesive tape 4 to which the holdable target 2 is affixed by the ultraviolet-curable adhesive and which is affixed to the frame 6. In treatment step S10 prior to delivery step S30, a dividing step is carried out to divide the plate-shaped holdable target 2 into individual chips.

The dividing step is performed by a cutting apparatus for cutting the holdable target 2 with a cutting blade, for example. The cutting apparatus includes, for example, a holding unit such as a chuck table for holding the holdable target 2 in position and a cutting unit for cutting the holdable target 2 held by the holding unit.

The holding unit includes a frame made of a material such as ceramic or metal, for example, and a suction member attached to the frame. The frame is of a substantially cylindrical shape as a whole and has a circular recess defined in an end face thereof.

The suction member includes a disk-shaped member made of porous ceramic or metal, for example. If the suction member is made of metal or the like, then it has a hole defined therein that extends axially, i.e., thicknesswise, therethrough.

The disk-shaped suction member is fitted in the circular recess defined in the frame. The frame has a fluid channel defined therein through which fluid such as gas can flow. An external suction source, not depicted, such as a vacuum pump is fluidly connected to the fluid channel. When the suction source is actuated, it generates and transmits a negative pressure to the fluid channel, attracting an object such as the holdable target 2 placed on the holding unit in contact with a holding surface of the suction member under a suction force developed thereon by the vacuum pressure transmitted through the holes of the suction member.

The cutting unit includes a spindle on which a cutting blade is mounted and a housing in which the spindle is rotatably supported. The cutting blade includes, for example, an annular base and an annular cutting edge mounted on the base along an outer circumferential edge of the base. The cutting edge is, for example, made of an electroformed grindstone including abrasive grains of diamond bound together by nickel plating.

The spindle is of a cylindrical shape and includes a blade mounter on one end thereof with the cutting blade mounted thereon. The other end of the spindle is coupled to a rotary actuator such as an electric motor. The cylindrical spindle is rotatably housed in the housing and has a horizontal axis. When the rotary actuator is energized, it rotates the spindle together with the cutting blade about the horizontal axis.

For dividing the holdable target 2 held by the holding unit, the cutting blade cuts into the holdable target 2 while rotating in unison with the spindle. While the cutting blade is cutting into the holdable target 2, the cutting unit and the holding unit are moved relatively to each other in a direction along the holding surface of the holding unit, dividing the holdable target 2 along the projected dicing lines thereon.

Alternatively, the cutting blade cuts into the holdable target 2, forming cut grooves in the holdable target 2 along the projected dicing lines thereon, after which an external force is applied to the holdable target 2 to divide the holdable target 2 along the cut grooves, for example.

In treatment step S20 after delivery step S30, a removing or peel-off step is carried out to peel off the chips from the adhesive tape 4 to obtain the chips, for example. Since the bonding power of the adhesive tape 4 has been reduced by the application of ultraviolet rays to the delivery target 8 in ultraviolet irradiation step S40 during delivery step S30, the chips can easily be peeled off from the adhesive tape 4.

In treatment steps S10 and S20, other steps other than the dividing step and the peel-off step described above may be carried out. For example, after the holdable target 2 has been divided, the delivery target 8 may be cleaned. When the peel-off step is carried out, a die-bonding step may concurrently be carried out on the peeled-off chips, and a wire-bonding step may also be carried out thereon.

The steps described above may automatically be performed according to programs stored in the memories of the controller 32, or may be performed by the operator via the operating unit 32b connected to the controller 32 (see FIG. 4). The operator may turn on and off the ultraviolet emitter 42 in the ultraviolet irradiator 40, adjust the output power of the ultraviolet emitter 42, move the delivery carriage 12 toward the ultraviolet irradiator 40, and control the speed of the delivery carriage 12 as it passes through the transmissive area 38b by entering operation commands into the operating unit 32b while referring to various pieces of information displayed on the display unit 32a, for example.

At this time, it is important to manage information indicative of the stage that each delivery target 8 is in while being subjected to treatment by each of the treatment apparatuses 34 or information indicative of whether each delivery target 8 has already been irradiated with ultraviolet rays or not. These items of information can be managed by the controller 32 that associates identification information of each delivery target 8 with the history of traveling details of each delivery carriage 12 that delivers a delivery target 8. The controller 32 or the operator distinguishes between those delivery targets 8 that have been irradiated with ultraviolet rays and those not irradiated with ultraviolet rays on the basis of the associated information, and irradiates the latter delivery targets 8 with ultraviolet rays, if necessary.

The structural and methodical details of the above embodiments are not restrictive, and various changes and modifications may be made therein without departing from the scope of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. An ultraviolet irradiation system for irradiating a delivery target with ultraviolet rays, comprising:
a delivery path along which to deliver the delivery target to a treatment apparatus; and
an ultraviolet irradiator for irradiating the delivery target delivered along the delivery path with ultraviolet rays, the ultraviolet irradiator being disposed in the delivery path and including an ultraviolet emitter for emitting ultraviolet rays.

2. The ultraviolet irradiation system according to claim 1,
wherein the delivery path includes at least a portion disposed above the treatment apparatus, and
the ultraviolet emitter is housed in a casing disposed in the portion of the delivery path disposed above the treatment apparatus.

3. The ultraviolet irradiation system according to claim 1, further comprising:
a delivery carriage movable on and along the delivery path,
wherein the delivery carriage includes
a frame having a plurality of wheels traveling on the delivery path,
a support for supporting the delivery target on the frame, and
a lifting and lowering unit mounted on the frame for suspending and lifting and lowering the delivery target through an opening defined in and vertically extending through the delivery path, and
the ultraviolet irradiator irradiates the delivery carriage on the delivery path with the ultraviolet rays.

4. The ultraviolet irradiation system according to claim 2, further comprising:
a delivery carriage movable on and along the delivery path,
wherein the delivery carriage includes
a frame having a plurality of wheels traveling on the delivery path,
a support for supporting the delivery target on the frame, and
a lifting and lowering unit mounted on the frame for suspending and lifting and lowering the delivery target through an opening defined in and vertically extending through the delivery path, and
the ultraviolet irradiator irradiates the delivery carriage on the delivery path with the ultraviolet rays.

5. The ultraviolet irradiation system according to claim 3,
wherein the ultraviolet irradiator is disposed to apply the ultraviolet rays from below a delivery surface of the delivery path to a region above the delivery surface, and
the delivery surface of a portion of the delivery path that is irradiated with the ultraviolet rays from therebelow is provided as a transmissive area that is made of a material that is transmissive of the ultraviolet rays.

6. The ultraviolet irradiation system according to claim 4,
wherein the ultraviolet irradiator is disposed to apply the ultraviolet rays from below a delivery surface of the delivery path to a region above the delivery surface, and
the delivery surface of a portion of the delivery path that is irradiated with the ultraviolet rays from therebelow is provided as a transmissive area that is made of a material that is transmissive of the ultraviolet rays.

7. The ultraviolet irradiation system according to claim 5,
wherein the delivery surface of the portion of the delivery path that is provided as the transmissive area lies flush with the delivery surface of the other portion of the delivery path.

8. The ultraviolet irradiation system according to claim 6,
wherein the delivery surface of the portion of the delivery path that is provided as the transmissive area lies flush with the delivery surface of the other portion of the delivery path.

9. The ultraviolet irradiation system according to claim 3,
wherein the support of the delivery carriage includes either a structure that supports the delivery target housed in a receptacle or a receptacle housing the delivery target therein, and
the receptacle has at least a portion made of a material that is transmissive of ultraviolet rays.

10. The ultraviolet irradiation system according to claim 4,
wherein the support of the delivery carriage includes either a structure that supports the delivery target housed in a receptacle or a receptacle housing the delivery target therein, and
the receptacle has at least a portion made of a material that is transmissive of ultraviolet rays.

11. The ultraviolet irradiation system according to claim 1,
wherein the delivery target includes a frame unit including
a plate-shaped holdable target,
a frame surrounding the holdable target, and
an adhesive tape to which the holdable target is affixed by an ultraviolet-curable adhesive and which is affixed to the frame.

12. The ultraviolet irradiation system according to claim 2,
wherein the delivery target includes a frame unit including
a plate-shaped holdable target,
a frame surrounding the holdable target, and
an adhesive tape to which the holdable target is affixed by an ultraviolet-curable adhesive and which is affixed to the frame.

13. An ultraviolet irradiation method of irradiating a delivery target with ultraviolet rays, the method comprising:
performing treatment on the delivery target with a treatment apparatus;
delivering the delivery target outside the treatment apparatus; and
irradiating the delivery target that is being delivered outside the treatment apparatus with ultraviolet rays.

14. The ultraviolet irradiation method according to claim 13,
wherein the irradiating the delivery target that is being delivered with the ultraviolet rays includes controlling a period of time during which the delivery target is irradiated with the ultraviolet rays by controlling at least either a speed at which the delivery target is delivered or a period of time during which the delivery target stops with respect to an ultraviolet irradiator that irradiates the delivery target with the ultraviolet rays.

15. A method of manufacturing chips with an ultraviolet irradiation method of irradiating a delivery target with ultraviolet rays, the method including
performing treatment on the delivery target with a treatment apparatus,
delivering the delivery target outside the treatment apparatus, and
irradiating the delivery target that is being delivered outside the treatment apparatus with ultraviolet rays,
the delivery target including a plate-shaped holdable target, a frame surrounding the holdable target, and an adhesive tape to which the holdable target is affixed by an ultraviolet-curable adhesive and which is affixed to the frame,
the method of manufacturing chips comprising:
before delivering the delivery target outside the treatment apparatus, dividing the holdable target into chips; and
after delivering the delivery target outside the treatment apparatus, removing the chips from the adhesive tape.

16. The method of manufacturing chips according to claim 15,
wherein the irradiating the delivery target that is being delivered with the ultraviolet rays includes controlling a period of time during which the delivery target is irradiated with the ultraviolet rays by controlling at least either a speed at which the delivery target is delivered or a period of time during which the delivery target stops with respect to an ultraviolet irradiator that irradiates the delivery target with the ultraviolet rays.
